(19) United States
(12) Patent Application Publication
(10) Pub. No.: US 2014/0258626 A1
(43) Pub. Date: Sep. 11, 2014

(54) ELECTRONIC DEVICES HAVING SEMICONDUCTOR MEMORY UNIT

(71) Applicant: SK Hynix Inc., Icheon-Si (KR)

(72) Inventor: Jung-Hyun Kang, Icheon-Si (KR)

(73) Assignee: SK Hynix Inc., Icheon-Si (KR)

(21) Appl. No.: 14/144,415

(22) Filed: Dec. 30, 2013

(30) Foreign Application Priority Data
Mar. 5, 2013 (KR) 10-2013-0023148

(51) Int. Cl. H01L 45/00; G06F 12/08; H01L 27/22; H01L 43/02; H01L 27/24

(52) U.S. Cl. CPC H01L 45/1253; H01L 43/02; H01L 27/2463; H01L 27/222; G06F 12/0813; G06F 12/0875
USPC 711/125; 257/4; 711/147

(57) ABSTRACT

An electronic device includes: a variable resistance element having a first electrode, a variable resistance layer, and a second electrode which are sequentially stacked therein; a spacer formed on the sidewall of the variable resistance element; and a conductive line covering the variable resistance element including the spacer.

### CROSS-REFERENCE TO RELATED APPLICATION

The present application claims priority of Korean Patent Application No. 10-2013-0023148, entitled “SEMICONDUCTOR DEVICE AND METHOD FOR MANUFACTURING THE SAME, AND MICRO PROCESSOR, PROCESSOR, SYSTEM, DATA STORAGE SYSTEM AND MEMORY SYSTEM INCLUDING THE SEMICONDUCTOR DEVICE” and filed on Mar. 5, 2013, which is incorporated herein by reference in its entirety.

### TECHNICAL FIELD

This patent document relates to an electronic device fabrication technology, and more particularly, to an electronic device including a variable resistance element to switch between different resistance states and a method for fabricating the electronic device.

### BACKGROUND

Recently, as electronic devices or appliances trend toward miniaturization, low power consumption, high performance, multi-functionality, and so on, there is a demand for semiconductor devices capable of storing information in various electronic devices or appliances such as a computer, a portable communication device, and so on, and research and development for such semiconductor devices have been conducted. Examples of such semiconductor devices include semiconductor devices which can store data using a characteristic switched between different resistance states according to an applied voltage or current, and can be implemented in various configurations, for example, an RRAM (resistive random access memory), a PRAM (phase change random access memory), an FRAM (ferroelectric random access memory), an MRAM (magnetic random access memory), an E-fuse, etc.

### SUMMARY

The disclosed technology in this patent document includes memory circuits or devices and their applications in electronic devices or systems and various implementations of an electronic device in which the device characteristic may be improved.

In one aspect, an electronic device is provided to include a semiconductor memory unit that includes: a variable resistance element having a first electrode, a variable resistance layer, and a second electrode which are sequentially stacked therein; a spacer formed on the sidewall of the variable resistance element; and a conductive line covering the variable resistance element including the spacer.

Implementations of the above electronic device may include one or more the following.

The electronic device may further include a microprocessor which includes: a control unit configured to receive a signal including a command from an outside of the microprocessor, and performs extracting, decoding of the command, or controlling input or output of a signal of the microprocessor; an operation unit configured to perform an operation based on a result that the control unit decodes the command; and a memory unit configured to store data for performing the operation, data corresponding to a result of performing the operation, or an address of data for which the operation is performed, wherein the semiconductor memory unit that includes the resistance variable element is part of the memory unit in the microprocessor.

The electronic device may further include a processor which includes: a core unit configured to perform, based on a command inputted from an outside of the processor, an operation corresponding to the command, by using data; a cache memory unit configured to store data for performing the operation, data corresponding to a result of performing the operation, or an address of data for which the operation is performed; and a bus interface connected between the core unit and the cache memory unit, and configured to transmit data between the core unit and the cache memory unit, wherein the semiconductor memory unit that includes the resistance variable element is part of the cache memory unit in the processor.

The electronic device may further include a processing system which includes: a processor configured to decode a command received by the processor and control an operation for information based on a result of decoding the command; an auxiliary memory device configured to store a program for decoding the command and the information; a main memory device configured to call and store the program and the information from the auxiliary memory device such that the processor can perform the operation using the program and the information when executing the program; and an interface device configured to perform communication between at least one of the processor, the auxiliary memory device and the main memory device and the outside, wherein the semiconductor memory unit that includes the resistance variable element is part of the auxiliary memory device or the main memory device in the processing system.

The electronic device may further include a data storage system which includes: a storage device configured to store data and conserve stored data regardless of power supply; a controller configured to control input and output of data to and from the storage device according to a command inputted form an outside; a temporary storage device configured to temporarily store data exchanged between the storage device and the outside; and an interface configured to perform communication between at least one of the storage device, the controller and the temporary storage device and the outside, wherein the semiconductor memory unit that includes the resistance variable element is part of the storage device or the temporary storage device in the data storage system.

The electronic device may further include a memory system which includes: a memory configured to store data and conserve stored data regardless of power supply; a memory controller configured to control input and output of data to and from the memory according to a command inputted form an outside; a buffer memory configured to buffer data exchanged between the memory and the outside; and an interface configured to perform communication between at least one of the memory, the memory controller and the buffer memory and the outside, wherein the semiconductor memory unit that includes the resistance variable element is part of the memory or the buffer memory in the memory system.

In another aspect, an electronic device is provided to include a semiconductor memory unit that includes: an interlayer dielectric layer formed over a substrate including a switching element; a contact plug connected to the switching element through the interlayer dielectric layer; a variable resistance element formed over the interlayer dielectric layer so as to be connected to the contact plug and including a first electrode, a variable resistance layer, and a second electrode which are stacked therein; a spacer formed on the sidewall of the variable resistance element; and a variable resistance element formed over the interlayer dielectric layer so as to cover the variable resistance element including the spacer.

In another aspect, a method is provided for fabricating an electronic device having a semiconductor memory unit. This method includes: forming an interlayer dielectric layer over a substrate including a switching element; forming a contact plug connected to the switching element through the interlayer dielectric layer; forming a variable resistance element over the interlayer dielectric layer so as to be connected to the contact plug, the variable resistance element including a first electrode, a variable resistance layer, and a second electrode which are stacked therein; forming a spacer on the sidewall of the variable resistance element; forming a conductive layer over the interlayer dielectric layer; and forming a conductive line covering the variable resistance element including the spacer by selectively etching the conductive layer.

In another aspect, a method is provided for fabricating an electronic device having a semiconductor memory unit. This method includes: providing a substrate including a switching element; forming an interlayer dielectric layer over the substrate; forming a contact plug in the interlayer dielectric layer such that the contact plug is connected to the switching element through the interlayer dielectric layer; forming a variable resistance element over the interlayer dielectric layer to connect to the contact plug, the variable resistance element including a stacked structure of a first electrode, a variable resistance layer, and a second; forming a spacer on a sidewall of the variable resistance element; forming a conductive layer over the interlayer dielectric layer; and forming a conductive line covering the variable resistance element including the spacer by selectively etching the conductive layer.

The forming of the variable resistance element may include forming a first conductive layer having a flat surface over the interlayer dielectric layer; forming a variable resistance layer over the first conductive layer; forming a second conductive layer over the variable resistance layer; forming a mask pattern over the second conductive layer; and etching the second conductive layer, the variable resistance layer, and the first conductive layer using the mask pattern as an etch barrier. The forming of the first conductive layer may include forming the first conductive layer over the interlayer dielectric layer; and performing a planarization process on the surface of the first conductive layer such that the interlayer dielectric layer is not exposed. The forming of the spacer may include forming an insulating layer along the surface of the resultant structure including the variable resistance element; and performing a blanket etch process on the insulating layer. The conductive layer may be formed to completely cover the variable resistance element including the spacer. Therein the forming of the conductive line may include performing a planarization process on the surface of the conductive layer such that the second electrode is not exposed; forming a mask pattern over the conductive layer; and etching the conductive layer using the mask pattern as an etch barrier. The conductive line may be electrically connected to the second electrode, and the variable resistance layer and the first electrode are electrically isolated from the conductive line by the spacer. The variable resistance layer may include a stacked layer of two magnetic layers with a tunnel barrier layer interposed therebetween. The variable resistance layer may include a metal oxide. The variable resistance layer may include a phase change material. The first electrode serves as a bottom electrode of the variable resistance element and has a minimum thickness sufficient to provide a flat surface between the first electrode and the variable resistance layer. The second electrode serves as a top electrode of the variable resistance element and has a reduced thickness as compared to that when the conductive line does not completely cover the variable resistance element. The first electrode serves as a bottom electrode of the variable resistance element and has a minimum thickness sufficient to provide a flat surface between the first electrode and the variable resistance layer. The second electrode serves as a top electrode of the variable resistance element and has a reduced thickness as compared to a thickness of the variable resistance element when the conductive line does not completely cover the variable resistance element.

Implementations of the above method may include one or more of the following.

These and other aspects, implementations and associated advantages are described in greater detail in the drawings, the description and the claims.

### BRIEF DESCRIPTION OF THE DRAWINGS

FIG. 1 is a cross-sectional view of a semiconductor structure as part of an electronic device.

FIGS. 2A and 2B are plan views of the semiconductor structure of the electronic device in FIG. 1.

FIGS. 3A to 3F are cross-sectional views illustrating a method for fabricating the semiconductor structure for the electronic device in FIG. 1.

FIG. 4 is an example of configuration diagram of a microprocessor implementing memory circuitry based on the disclosed technology.

FIG. 5 is an example of configuration diagram of a processor implementing memory circuitry based on the disclosed technology.

FIG. 6 is an example of configuration diagram of a system implementing memory circuitry based on the disclosed technology.

FIG. 7 is an example of configuration diagram of a data storage system implementing memory circuitry based on the disclosed technology.

FIG. 8 is an example of configuration diagram of a memory system implementing memory circuitry based on the disclosed technology.

### DETAILED DESCRIPTION

Various examples and implementations of the disclosed technology are described below in detail with reference to the accompanying drawings.

The drawings may not be necessarily to scale and in some instances, proportions of at least some of structures in the drawings may have been exaggerated in order to clearly illustrate certain features of the described examples or implementations. In presenting a specific example in a drawing or description having two or more layers in a multi-layer structure, the relative positioning relationship of such layers or the sequence of arranging the layers as shown reflects a particular implementation for the described or illustrated example and a different relative positioning relationship or sequence of arranging the layers may be possible. In addition, a described or illustrated example of a multi-layer structure may not reflect all layers present in that particular multilayer structure (e.g., one or more additional layers may be present between two illustrated layers). As a specific example, when a first layer in a described or illustrated multi-layer structure is referred to as being “on” or “over” a second layer or “on” or “over” a substrate, the first layer may be directly formed on the second layer or the substrate but may also represent a structure where one or more other intermediate layers may exist between the first layer and the second layer or the substrate.

The disclosed technology can be used to construct an electronic device which is capable of improving device characteristics and securing or improving a process margin, and to provide a method for fabricating the electronic device. More specifically, examples are provided for an electronic device which is capable of improving characteristics of a device including a variable resistance element and improving a process margin, and for a method for fabricating such an electronic device. In general, an electronic device including a variable resistance element has a conductive line coupled to the variable resistance element. With the increase in integration degree of the electronic device, a contact defect can frequently occur between the variable resistance element and the conductive line, thereby degrading the device characteristics or performance. The present implementations provide an electronic device including a conductive line to cover a variable resistance element and a method for fabricating the electronic device.

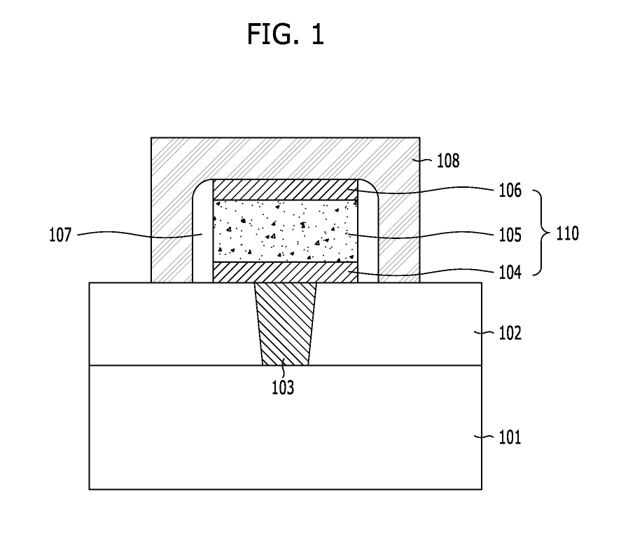

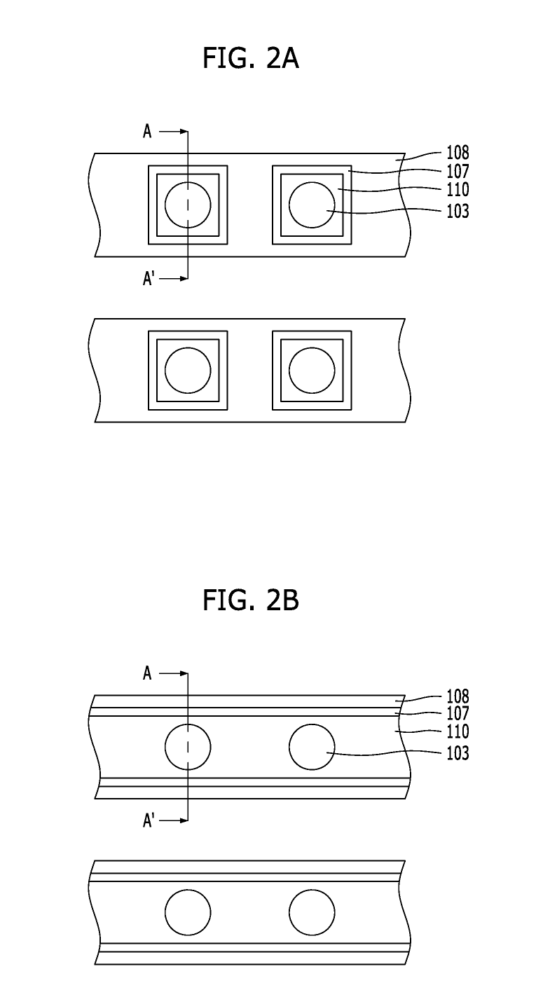

FIG. 1 is a cross-sectional view of a semiconductor structure having a variable resistance element in an electronic device in accordance with one example of implementation. FIGS. 2A and 2B are plan views of the electronic devices in accordance with various implementations. FIG. 1 is a cross-sectional view taken along lines A-A′ of FIGS. 2A and 2B.

Referring to FIGS. 1, 2A, and 2B, the electronic device includes a variable resistance element 110, a spacer 107 formed on the sidewall of the variable resistance element 110, and a conductive line 108 covering the variable resistance element 110 including the spacer 107. The variable resistance element 110 has a stacked structure of a first electrode 104, a variable resistance layer 105, and a second electrode 106. The second electrode 106 may be electrically connected to the variable resistance element 110, and the variable resistance layer 105 and the first electrode 104 may be electrically isolated from the conductive line 108 by the spacer 107. Furthermore, the conductive line 108 has a shape to completely cover the variable resistance element 110 including the spacer 107.

The variable resistance element 110 can have a characteristic of switching between different resistance states (or different resistance values) according to a bias (for example, voltage or current) applied through the first electrode 104 or the second electrode 106 or both the electrodes 104 and 106. Such a characteristic of having a variable resistance may be utilized in various fields. For example, the variable resistance element 110 may be used as a data storage to store data.

The variable resistance layer 105 in a storage device may has a variable resistance characteristic through a bias applied through the first electrode 104 or the second electrode 106 or the both, and may include a single layer or multilayer. For example, the variable resistance layer 105 may include a phase change material. The phase change material may include a chalcogen compound. The phase change material changes to an amorphous state or crystal state according to an external stimulus (for example, voltage or current), and may have a characteristic of switching between different resistance states. Furthermore, the variable resistance layer 105 may include a metal oxide. The metal oxide may include a transition metal oxide (TMO) and a perovskite-based oxide. The metal oxide may include vacancies therein, and may have a characteristic of switching between different resistance states through generation/presence, a change or disappearance of a conductive path depending on the behavior of vacancies by an external stimulus. Furthermore, the variable resistance layer 105 may include a stacked layer of two magnetic layers with a tunnel barrier layer interposed therebetween to form a magnetic tunnel junction (MTJ). The stacked layer of two magnetic layers with a tunnel barrier layer interposed therebetween may have a characteristic of switching between different resistance states according to the magnetization directions of the two magnetic layers. For example, when the magnetization directions of the two magnetic layers are identical to each other (or parallel to each other), the stacked layer may have a low resistance state, and when the magnetization directions of the two magnetic layers are different from each other (or anti-parallel to each other), the stacked layer may have a high resistance state. However, the present implementation is not limited thereto. The variable resistance layer 105 may include any materials which exhibit a variable resistance characteristic of switching between different resistance states according to a bias applied to the first electrode 104 or/and the second electrode 106.

The first electrode 104, the second electrode 106, and the conductive line 108 may include a metallic layer. The metallic layer can include a conductive layer including a metal element, and may include metal, metal oxide, metal nitride, metal oxynitride, metal silicide and the like.

The first electrode 104 may serve as a bottom electrode of the variable resistance element 110 and may have a flat surface. In one implementation, the flat surface constitutes an interface between the first electrode 104 and the variable resistance layer 105. Such a structure can be used to prevent the characteristic of the variable resistance layer 105 from being degraded by a level difference on the surface of the first electrode 104. In this structure, the first electrode 104 may have a thickness beyond a minimum thickness to implement a flat surface on the top for interfacing with the variable resistance layer 105, even though a level difference on the surface of a lower structure is reflected to the first electrode 104. For example, the first electrode 104 may have a sufficient thickness, e.g., of at least 50 Å or more, to allow for planarization of its top surface for supporting and interfacing with the variable resistance layer 105. In absence of the above method of providing a top flat surface of the first electrode 104 given an existence of a level difference in the first electrode 104 the corresponding level difference on the top surface of the first electrode 104 can be reflected to the variable resistance layer 105 subsequently formed on top of the first electrode 104. This reflected d level difference in the variable resistance layer 105 may cause wiggling, crack, coupling or the like to occur in the variable resistance layer 105, thereby degrading the characteristic of the variable resistance layer 105.

The second electrode 106 may serve as a top electrode of the variable resistance element 110, and protect the variable resistance layer 105 and the first electrode 104 during processes for the remainder of the fabrication. In various implementations, the second electrode 106 is formed to have a sufficient thickness, for example, a thickness of at least 500 Å or more, to provide a substantially flat top surface in order to prevent a defective contact between the conductive line 108 and the second electrode 106. In the present implementation shown in FIGS. 1, 2A and 2B, the conductive line 108 is shaped to cover the entire variable resistance element 110 including the spacer 107 to establish a large overall electrical contact area between the second electrode 106 and the conductive line 108 so that a defective contact between the variable resistance element 110 and the conductive line 108 can be substantially avoided or the adverse effect of such a defective contact can be reduced. Thus, under the designs in FIGS. 1, 2A and 2B, the tolerance to the presence of a defective contact is enhanced by the overall large contact area with the conductive line 108. Accordingly, the thickness of the second electrode 106 may be reduced. As a result, a margin for the process of forming the variable resistance element 110 and a thickness margin for the first electrode 104 and the variable resistance layer 105 may be increased, thereby improving the characteristic of the variable resistance element 110.

The spacer 107 formed on the sidewall of the variable resistance element 110 may be shaped to surround the entire sidewall of the variable resistance element 110. For example, the spacer 107 may be shaped to surround at least the sidewalls of the first electrode 104 and the variable resistance layer 105 of the variable resistance element 110. The spacer 107 may include an insulating material. For example, the spacer 107 may include any single layer including oxide, nitride, or oxynitride, or a stacked layer having two or more single layers that stack together.

Furthermore, the electronic device in accordance with the present implementation may further include a substrate 101, an interlayer dielectric layer 102, and a contact plug 103. The substrate 101 includes a predetermined structure including, for example, a switching element and the like. The interlayer dielectric layer 102 is formed over the substrate 101. The contact plug 103 electrically connects one end of a switching element to the variable resistance element 110 through the interlayer dielectric layer 102. The variable resistance element 110, the spacer 107, and the conductive line 108 may be formed over the interlayer dielectric layer 102.

The switching element for selecting a specific unit cell in the electronic device including a plurality of unit cells may be disposed in each of the unit cells, and may include a transistor, a diode and the like. One end of the switching element may be electrically connected to the contact plug 103 as described below, and the other end of the switching element may be electrically connected to a wiring (not illustrated), for example, a source line.

The contact plug 103 may include a semiconductor layer or metallic layer, and the variable resistance element 110 may have a critical dimension (CD) or area greater than the CD or area of the contact plug 103. Furthermore, the surface of the contact plug 103 may have the same level as the surface of the interlayer dielectric layer 102 or a lower level than the surface of the interlayer dielectric layer 102. When the surface of the contact plug 103 has a lower level than the surface of the interlayer dielectric layer 102, the first electrode 104 may fill the space formed by the level difference between the contact plug and the interlayer dielectric layer 102. The contact plug 103 may be connected to the first electrode 104 of the variable resistance element 110. A plurality of variable resistance elements 110 may be arranged in the conductive line 108 so as to contact the contact plugs 103, respectively. The plurality of variable resistance elements 110 may be arranged apart from one another (as shown in FIG. 2A). Furthermore, a line-type variable resistance element 110 may be arranged in the conductive line 108, and a plurality of contact plugs 103 may be connected to one variable resistance element 110 (as shown in FIG. 2B).

According to the electronic device having the above-described structure, the conductive line 108 is shaped to cover the variable resistance element 110, thereby preventing a defective contact between the conductive line 108 and the variable resistance element 110 and reducing contact resistance between the variable resistance element 110 and the conductive line 108. Thus, it is possible to improve the signal transmission characteristic of the electronic device. Further, when compared to the damascene processing for forming a conductive structure connecting the conductive line 108 and the second electrode 106, for example, a structure including a contact plug or a structure including a damascene pattern buried therein to expose the second electrode 106 through the conductive line 108, the present implementation provides a simple structure and a sufficiently large contact area, thereby improving a process margin.

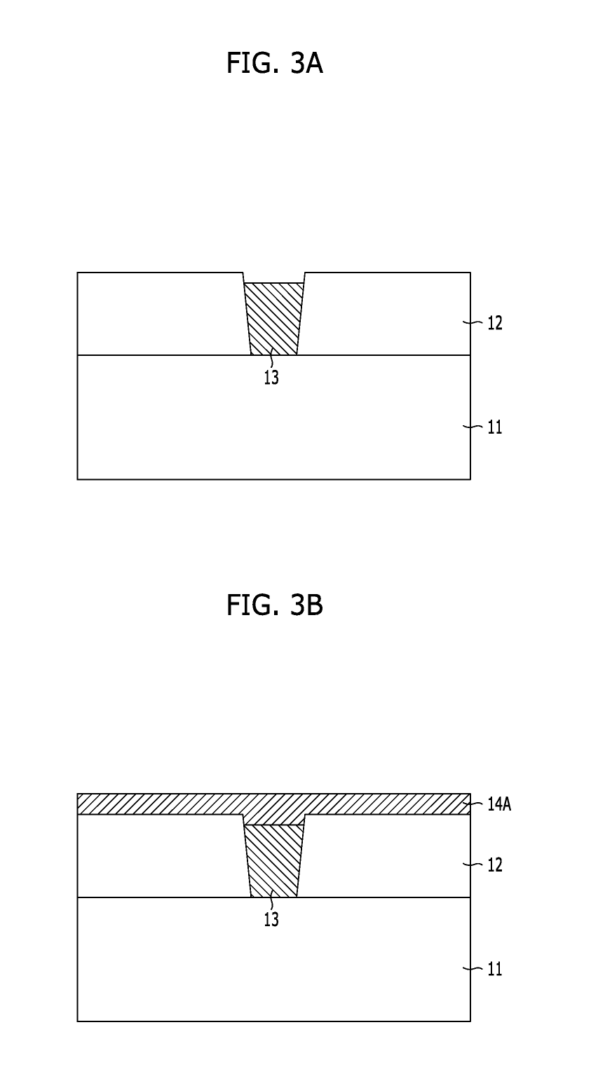

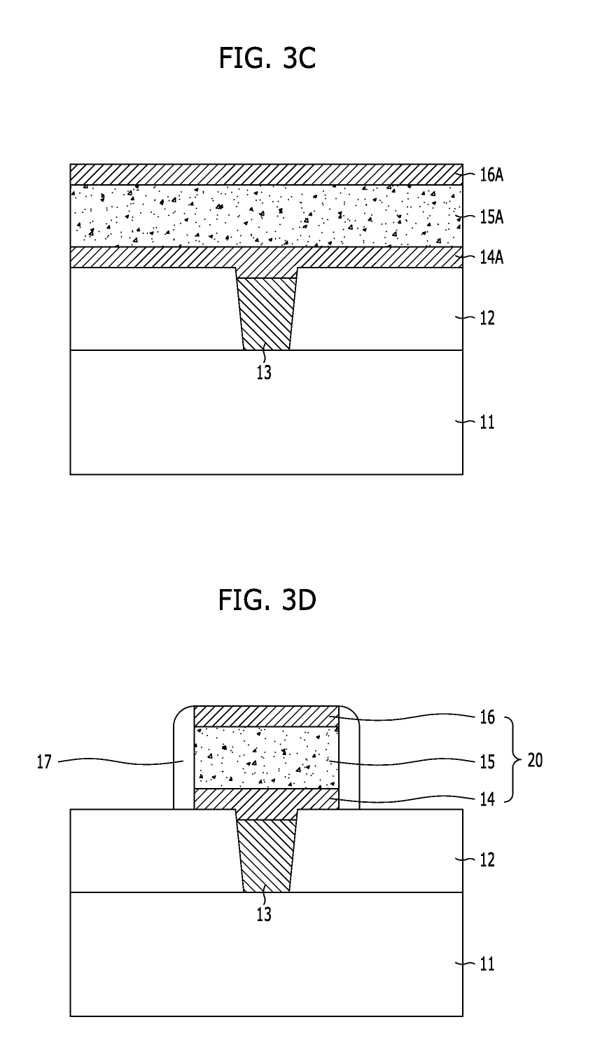

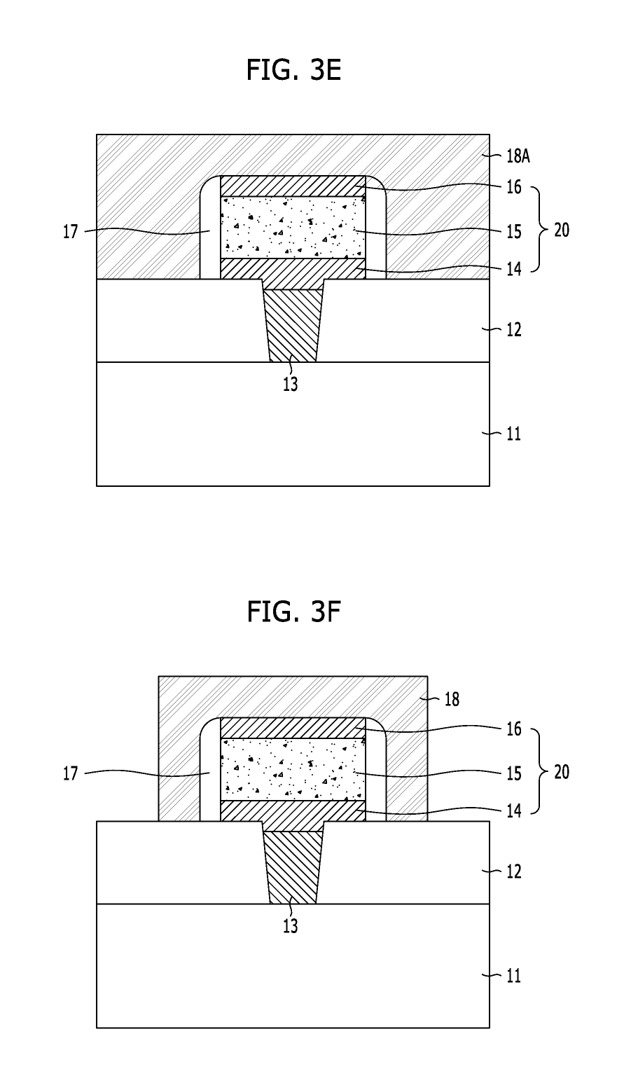

FIGS. 3A to 3F are cross-sectional views illustrating a method for fabricating an electronic device in accordance with an implementation. FIGS. 3A to 3F illustrate an example of a method for fabricating the electronic device of FIG. 1.

Referring to FIG. 3A, a substrate having a predetermined structure including, for example, a switching element (not illustrated) or the like is provided. The switching element is coupled to serve a specific unit cell by turning on or turning off the unit cell in an electronic device including a plurality of unit cells, and such a switching element may include a transistor, a diode and the like. One end of the switching element for a unit cell may be electrically connected to a contact plug as described below, and the other end of the switching element may be electrically connected to a wiring (not illustrated), for example, a source line.

An interlayer dielectric layer 12 is formed over the substrate 11. The interlayer dielectric layer 12 may include any single layer including oxide, nitride, or oxynitride, or a stacked layer of two or more single layers.

A contact plug 13 is formed to be electrically connected to one end of the switching element through the interlayer dielectric layer 12. The contact plug 13 serves to electrically connect the switching element to a variable resistance element to be formed during a subsequent process, and serves as an electrode for the variable resistance element, for example, a bottom electrode. The contact plug 13 may be formed of a semiconductor layer or metal layer. The semiconductor layer may include silicon, and the metal layer may include metal, metal oxide, metal nitride, metal oxynitride, metal silicide and the like.

The contact plug 13 may be formed through the following series of processes: the interlayer dielectric layer 12 is selectively etched to form a contact hole to expose one end of the switching element in the substrate 11, a conductive material is formed on the entire surface of the resultant structure so as to fill the contact hole, and an isolation process is performed to electrically isolate the adjacent contact plugs 13. The isolation process may be performed by etching or polishing the conductive material formed on the entire surface of the resultant structure through a blanket etch process (for example, etch-back process) or chemical mechanical polishing (CMP) process, until the interlayer dielectric layer 12 is exposed.

During the above-described process for forming the contact plugs 13, a level difference between the surface of the interlayer dielectric layer 12 and the surface of the contact plug 13 may occur due to a difference in selectivity between the interlayer dielectric layer 12 and the contact plug 13, that is, between the interlayer dielectric layer 12 and the conductive material. During the isolation process, a material having a greater selectivity with regard to the conductive material than the insulating material may be used. For example, a material may be selected which allows to remove the conductive material at a higher speed than the insulating material. Thus, the surface of the contact plug 13 may be formed at a lower level than the surface of the interlayer dielectric layer 12.

Referring to FIG. 3B, a first conductive layer 14A is formed over the interlayer dielectric layer 12 including the contact plug 13. The first conductive layer 14A may serve as a first electrode, for example, a bottom electrode, of a variable resistance element to be formed during a subsequent process, and may be formed of a metallic layer. The first conductive layer 14A may be formed to have a sufficient thickness, for example, a thickness of at least 50 Å or more. Thus, although the level difference of the lower structure is transferred to the first conductive layer 14A, the level difference can be easily removed or reduced by a planarization process described below.

Next, a planarization process is performed on the surface of the first conductive layer 14A. The planarization process for removing a level difference on the surface of the first conductive layer 14A is performed in such a manner that the interlayer dielectric layer 12 is not exposed. The planarization process serves to prevent wiggling, crack, coupling or the like from occurring in a variable resistance layer 15A to be formed over the first conductive layer 14A during a subsequent process, and may be performed through CMP. After the planarization process is completed, the first conductive layer 14A may have a flat surface, and may be shaped to fill the space formed by the level difference between the interlayer dielectric layer 12 and the contact plug 13.

If a flat surface can be obtained in forming the first conductive layer 14A, the planarization process for the surface of the first conductive layer 14A may be omitted.

Referring to FIG. 3C, a variable resistance layer 15A is formed over the first conductive layer 14A. The variable resistance layer 15A may include a material that can function to switch between different resistance states according to an external stimulus to provide a desired variable resistance characteristic. For example, the variable resistance layer 15A may include a phase change material layer, a metal oxide layer, or a stacked layer of two magnetic layers with a tunnel barrier layer interposed therebetween.

A second conductive layer 16A is formed over the variable resistance layer 15A. The second conductive layer 16A serves as a second electrode, for example, a top electrode, of a variable resistance element to be formed in a subsequent process, and may be formed of a metallic layer.

In FIG. 3D, a mask pattern (not illustrated) is formed over the second conductive layer 16A. The second conductive layer 16A, the variable resistance layer 15A, and the first conductive layer 14A are sequentially etched using the mask pattern as an etch barrier. The etch process may be performed through a dry etch process.

Thus, the variable resistance element 20 is formed to have a stacked structure of the first electrode 14, the variable resistance layer 15, and the second electrode 16. The second electrode 16 may serve as a mask pattern and an etch barrier during the etch process. The variable resistance element 20 may be formed in a line shape extended in a direction where a conductive line is extended, which will be formed during a subsequent process. In various implementations, a plurality of pillar-type variable resistance elements 20 may be arranged and spaced at a predetermined distance apart from one another in the direction where the conductive line is extended. Furthermore, the variable resistance element 20 may be formed to have a CD or area to cover the contact plug 13.

A spacer 17 is formed on the sidewall of the variable resistance element 20. The spacer 17 may be formed to surround the entire sidewall of the variable resistance element 20. Specifically, the spacer 17 may be formed to surround at least the exposed sidewalls of the first electrode 14 and the variable resistance layer 15.

The spacer 17 may be formed of an insulating layer. Specifically, the spacer 17 may include any single layer including oxide, nitride, or oxynitride, or a stacked layer of two or more single layers. The spacer 17 may be formed through a series of processes of forming an insulating layer along the surface of the structure including the variable resistance element 20 and then performing a blanket etch process, for example, an etch-back process.

Referring to FIG. 3E, a third conductive layer 18A is formed over the interlayer dielectric layer 12. At this time, the third conductive layer 18A may be formed to cover the variable resistance element 20 including the spacer 17. The third conductive layer 18A may be formed of a metallic layer.

A planarization process is performed on the surface of the third conductive layer 18A such that the second electrode 16 of the variable resistance element 20 is not exposed. The planarization process serves to remove a level difference on the surface of the third conductive material 18A, caused by the variable resistance element 20 formed over the interlayer dielectric layer 12. and the planarization process may be performed through CMP.

Referring to FIG. 3F, a mask pattern (not illustrated) is formed over the third conductive layer 18A, and the mask pattern is used as an etch barrier to etch the third conductive layer 18A until the interlayer dielectric layer 12 is exposed. Then, a conductive line 18 is formed. The conductive line 18 may be formed to cover the variable resistance element 20 including the spacer 17. The conductive line 18 may be formed to completely cover the variable resistance element 20 including the spacer 17. The conductive line 18 may be formed to be electrically connected to the second electrode 16 and electrically isolated from the variable resistance layer 15 and the first electrode 14 by the spacer 17.

The electronic device formed through the above-described fabrication process provides a structure in which the conductive line 18 covers the variable resistance element 20. Thus, the electronic device may prevent a defective contact between the conductive line 18 and the variable resistance element 20, and may reduce contact resistance between the variable resistance element 20 and the conductive line 18, which makes it possible to improve the signal transmission characteristic of the electronic device.

The electronic device formed through the above-described fabrication process provides a simple structure in which the conductive line 18 covers the variable resistance element 20, thereby remarkably increasing a margin for the fabrication process for implementing the electronic device.

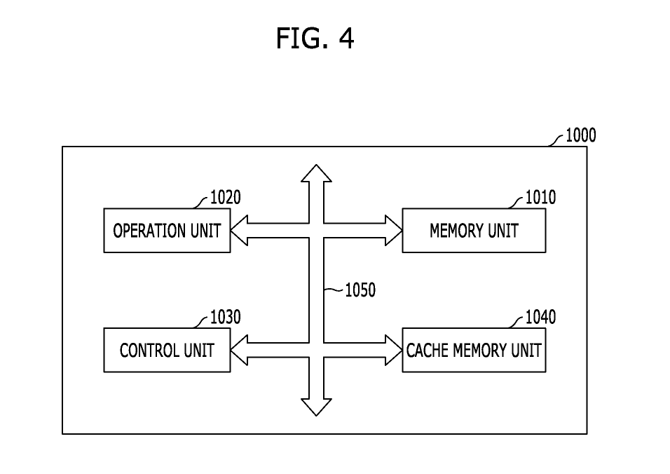

The above and other memory circuits or semiconductor devices based on the disclosed technology can be used in a range of devices or systems. FIGS. 4-8 provide some examples of devices or systems that can implement the memory circuits disclosed herein.

FIG. 4 is an example of configuration diagram of a microprocessor implementing memory circuitry based on the disclosed technology.

Referring to FIG. 4, a microprocessor 1000 may perform tasks for controlling and tuning a series of processes of receiving data from various external devices, processing the data, and outputting processing results to external devices. The microprocessor 1000 may include a memory unit 1010, an operation unit 1020, a control unit 1030, and so on. The microprocessor 1000 may be various data processing units such as a central processing unit (CPU), a graphic processing unit (GPU), a digital signal processor (DSP) and an application processor (AP).

The memory unit 1010 is a part which stores data in the microprocessor 1000, as a processor register, register or the like. The memory unit 1010 may include a data register, an address register, a floating point register and so on. Besides, the memory unit 1010 may include various registers. The memory unit 1010 may perform the function of temporarily storing data for which operations are to be performed by the operation unit 1020, result data of performing the operations and addresses where data for performing of the operations are stored.

The memory unit 1010 may include one or more of the above-described semiconductor devices in accordance with the implementations. For example, the memory unit 1010 may include a a variable resistance element including a stacked structure of a first electrode, a variable resistance layer, and a second electrode; a spacer formed on a sidewall of the variable resistance element; and a conductive line covering the variable resistance element including the spacer. By the conductive line which covers the variable resistance element including the spacer, a contact resistance between the conductive line and the variable resistance element can be decreased and a contact defect between the conductive line and the variable resistance element is prevented. Through this, operating characteristic of the memory unit 1010 and the micro processor 1000 having the memory unit 1010 is improved. As a consequence, it is possible to realize a high performance of the micro processor 1000.

The operation unit 1020 may perform four arithmetical operations or logical operations according to results that the control unit 1030 decodes commands. The operation unit 1020 may include at least one arithmetic logic unit (ALU) and so on.

The control unit 1030 may receive signals from the memory unit 1010, the operation unit 1020 and an external device of the microprocessor 1000, perform extraction, decoding of commands, and controlling input and output of signals of the microprocessor 1000, and execute processing represented by programs.

The microprocessor 1000 according to the present implementation may additionally include a cache memory unit 1040 which can temporarily store data to be inputted from an external device other than the memory unit 1010 or to be outputted to an external device. In this case, the cache memory unit 1040 may exchange data with the memory unit 1010, the operation unit 1020 and the control unit 1030 through a bus interface 1050.

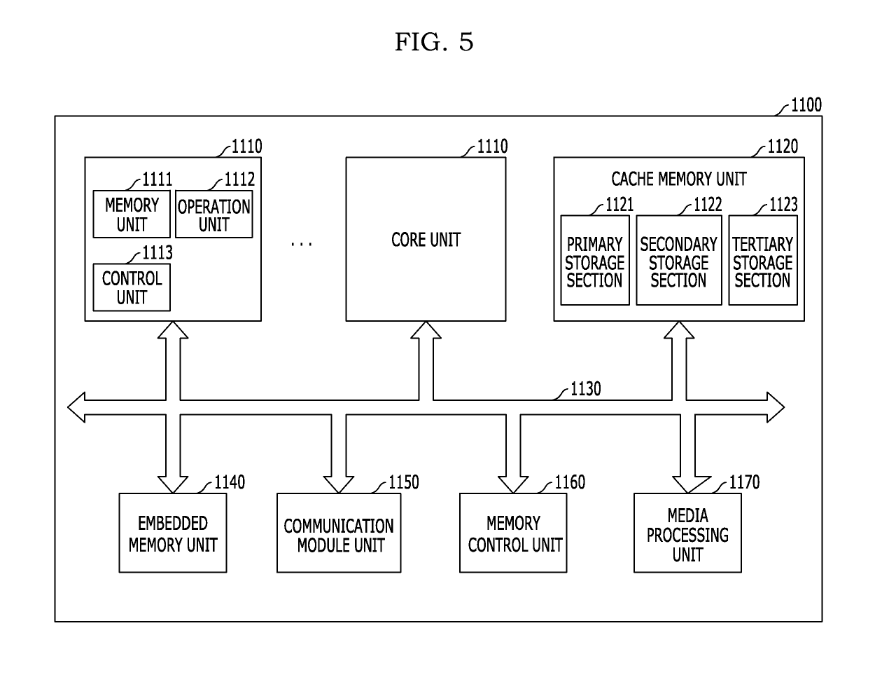

FIG. 5 is an example of configuration diagram of a processor implementing memory circuitry based on the disclosed technology.

Referring to FIG. 5, a processor 1100 may improve performance and realize multi-functionality by including various functions other than those of a microprocessor which performs tasks for controlling and tuning a series of processes of receiving data from various external devices, processing the data, and outputting processing results to external devices. The processor 1100 may include a core unit 1110 which serves as the microprocessor, a cache memory unit 1120 which serves to storing data temporarily, and a bus interface 1130 for transferring data between internal and external devices. The processor 1100 may include various system-on-chips (SoCs) such as a multi-core processor, a graphic processing unit (GPU) and an application processor (AP).

The core unit 1110 of the present implementation is a part which performs arithmetic logic operations for data inputted from an external device, and may include a memory unit 1111, an operation unit 1112 and a control unit 1113.

The memory unit 1111 is a part which stores data in the processor 1100, as a processor register, a register or the like. The memory unit 1111 may include a data register, an address register, a floating point register and so on. Besides, the memory unit 1111 may include various registers. The memory unit 1111 may perform the function of temporarily storing data for which operations are to be performed by the operation unit 1112, result data of performing the operations and addresses where data for performing of the operations are stored. The operation unit 1112 is a part which performs operations in the processor 1100. The operation unit 1112 may perform four arithmetical operations, logical operations, according to results that the control unit 1113 decodes commands, or the like. The operation unit 1112 may include at least one arithmetic logic unit (ALU) and so on. The control unit 1113 may receive signals from the memory unit 1111, the operation unit 1112 and an external device of the processor 1100, perform extraction, decoding of commands, controlling input and output of signals of processor 1100, and execute processing represented by programs.

The cache memory unit 1120 is a part which temporarily stores data to compensate for a difference in data processing speed between the core unit 1110 operating at a high speed and an external device operating at a low speed. The cache memory unit 1120 may include a primary storage section 1121, a secondary storage section 1122 and a tertiary storage section 1123. In general, the cache memory unit 1120 includes the primary and secondary storage sections 1121 and 1122, and may include the tertiary storage section 1123 in the case where high storage capacity is required. As the occasion demands, the cache memory unit 1120 may include an increased number of storage sections. That is to say, the number of storage sections which are included in the cache memory unit 1120 may be changed according to a design. The speeds at which the primary, secondary and tertiary storage sections 1121, 1122 and 1123 store and discriminate data may be the same or different. In the case where the speeds of the respective storage sections 1121, 1122 and 1123 are different, the speed of the primary storage section 1121 may be largest. At least one storage section of the primary storage section 1121, the secondary storage section 1122 and the tertiary storage section 1123 of the cache memory unit 1120 may include one or more of the above-described semiconductor devices in accordance with the implementations. For example, the cache memory unit 1120 may include a variable resistance element including a stacked structure of a first electrode, a variable resistance layer, and a second electrode; a spacer formed on a sidewall of the variable resistance element; and a conductive line covering the variable resistance element including the spacer. By using the conductive line which covers the variable resistance element including the spacer, a contact resistance between the conductive line and the variable resistance element is decreased and a contact defect between the conductive line and the variable resistance element is prevented. Through this, operating characteristic of the cache memory unit 1120 and the processor 1100 having the cache memory unit 1120 is improved. As a consequence, it is possible to realize a high performance of the processor 1100.

Although it was shown in FIG. 9 that all the primary, secondary and tertiary storage sections 1121, 1122 and 1123 are configured inside the cache memory unit 1120, it is to be noted that all the primary, secondary and tertiary storage sections 1121, 1122 and 1123 of the cache memory unit 1120 may be configured outside the core unit 1110 and may compensate for a difference in data processing speed between the core unit 1110 and the external device. Meanwhile, it is to be noted that the primary storage section 1121 of the cache memory unit 1120 may be disposed inside the core unit 1110 and the secondary storage section 1122 and the tertiary storage section 1123 may be configured outside the core unit 1110 to strengthen the function of compensating for a difference in data processing speed. In another implementation, the primary and secondary storage sections 1121, 1122 may be disposed inside the core units 1110 and tertiary storage sections 1123 may be disposed outside core units 1110.

The bus interface 1130 is a part which connects the core unit 1110, the cache memory unit 1120 and external device and allows data to be efficiently transmitted.

The processor 1100 according to the present implementation may include a plurality of core units 1110, and the plurality of core units 1110 may share the cache memory unit 1120. The plurality of core units 1110 and the cache memory unit 1120 may be directly connected or be connected through the bus interface 1130. The plurality of core units 1110 may be configured in the same way as the above-described configuration of the core unit 1110. In the case where the processor 1100 includes the plurality of core unit 1110, the primary storage section 1121 of the cache memory unit 1120 may be configured in each core unit 1110 in correspondence to the number of the plurality of core units 1110, and the secondary storage section 1122 and the tertiary storage section 1123 may be configured outside the plurality of core units 1110 in such a way as to be shared through the bus interface 1130. The processing speed of the primary storage section 1121 may be larger than the processing speeds of the secondary and tertiary storage section 1122 and 1123. In another implementation, the primary storage section 1121 and the secondary storage section 1122 may be configured in each core unit 1110 in correspondence to the number of the plurality of core units 1110, and the tertiary storage section 1123 may be configured outside the plurality of core units 1110 in such a way as to be shared through the bus interface 1130.

The processor 1100 according to the present implementation may further include an embedded memory unit 1140 which stores data, a communication module unit 1150 which can transmit and receive data to and from an external device in a wired or wireless manner, a memory control unit 1160 which drives an external memory device, and a media processing unit 1170 which processes the data processed in the processor 1100 or the data inputted from an external input device and outputs the processed data to an external interface device and so on. Besides, the processor 1100 may include a plurality of various modules and devices. In this case, the plurality of modules which are added may exchange data with the core units 1110 and the cache memory unit 1120 and with one another, through the bus interface 1130.

The embedded memory unit 1140 may include not only a volatile memory but also a nonvolatile memory. The volatile memory may include a DRAM (dynamic random access memory), a mobile DRAM, an SRAM (static random access memory), and a memory with similar functions to above mentioned memories, and so on. The nonvolatile memory may include a ROM (read only memory), a NOR flash memory, a NAND flash memory, a phase change random access memory (PRAM), a resistive random access memory (RRAM), a spin transfer torque random access memory (STTRAM), a magnetic random access memory (MRAM), a memory with similar functions.

The communication module unit 1150 may include a module capable of being connected with a wired network, a module capable of being connected with a wireless network and both of them. The wired network module may include a local area network (LAN), a universal serial bus (USB), an Ethernet, power line communication (PLC) such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB) such as various devices which send and receive data without transmit lines, and so on.

The memory control unit 1160 is to administrate and process data transmitted between the processor 1100 and an external storage device operating according to a different communication standard. The memory control unit 1160 may include various memory controllers, for example, devices which may control IDE (Integrated Device Electronics), SATA (Serial Advanced Technology Attachment), SCSI (Small Computer System Interface), RAID (Redundant Array of Independent Disks), an SSD (solid state disk), eSATA (External SATA), PCMCIA (Personal Computer Memory Card International Association), a USB (universal serial bus), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The media processing unit 1170 may process the data processed in the processor 1100 or the data inputted in the forms of image, voice and others from the external input device and output the data to the external interface device. The media processing unit 1170 may include a graphic processing unit (GPU), a digital signal processor (DSP), a high definition audio device (HD audio), a high definition multimedia interface (HDMI) controller, and so on.

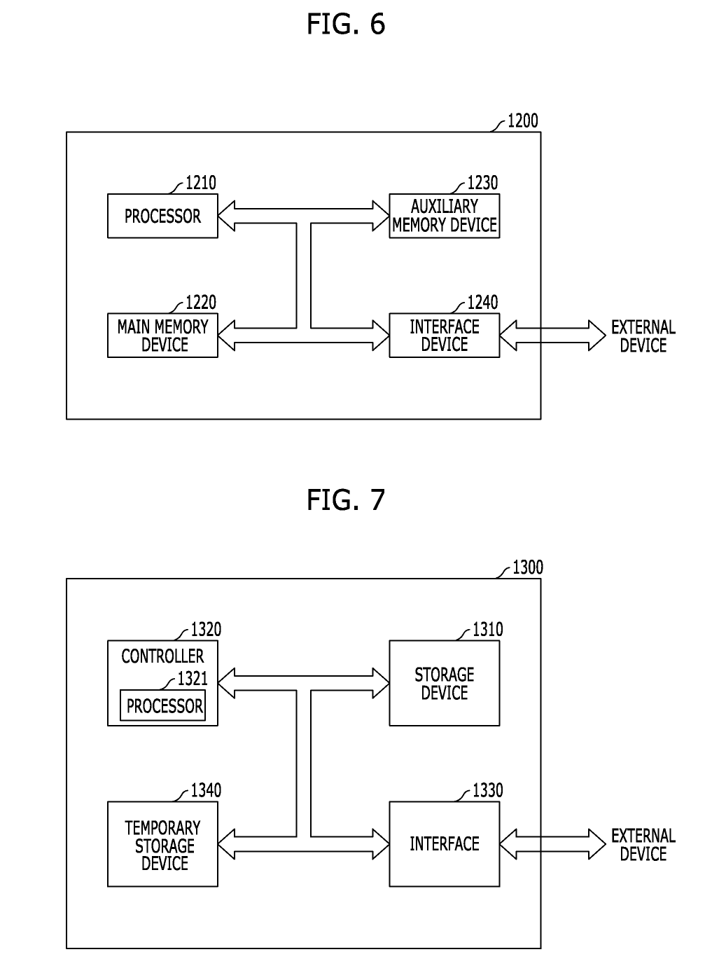

FIG. 6 is an example of configuration diagram of a system implementing memory circuitry based on the disclosed technology.

Referring to FIG. 6, a system 1200 as an apparatus for processing data may perform input, processing, output, communication, storage, etc. to conduct a series of manipulations for data. The system 1200 may include a processor 1210, a main memory device 1220, an auxiliary memory device 1230, an interface device 1240, and so on. The system 1200 of the present implementation may be various electronic systems which operate using processors, such as a computer, a server, a PDA (personal digital assistant), a portable computer, a web tablet, a wireless phone, a mobile phone, a smart phone, a digital music player, a PMP (portable multimedia player), a camera, a global positioning system (GPS), a video camera, a voice recorder, a telematics, an audio visual (AV) system, a smart television, and so on.

The processor 1210 may decode inputted commands and processes operation, comparison, etc. for the data stored in the system 1200, and controls these operations. The processor 1210 may include a microprocessor unit (MPU), a central processing unit (CPU), a single/multi-core processor, a graphic processing unit (GPU), an application processor (AP), a digital signal processor (DSP), and so on.

The main memory device 1220 is a storage which can temporarily store, call and execute program codes or data from the auxiliary memory device 1230 when programs are executed and can conserve memorized contents even when power supply is cut off. The main memory device 1220 may include one or more of the above-described semiconductor devices in accordance with the implementations. For example, the main memory device 1220 may include a variable resistance element including a stacked structure of a first electrode, a variable resistance layer, and a second electrode; a spacer formed on a sidewall of the variable resistance element; and a conductive line covering the variable resistance element including the spacer. By using the conductive line which covers the variable resistance element including the spacer, a contact resistance between the conductive line and the variable resistance element is decreased and a contact defect between the conductive line and the variable resistance element is prevented. Through this, operating characteristic of the main memory device 1220 and the system 1200 having the main memory device 1220 can be improved. As a consequence, it is possible to realize a high performance of the system 1200.

Also, the main memory device 1220 may further include a static random access memory (SRAM), a dynamic random access memory (DRAM), and so on, of a volatile memory type in which all contents are erased when power supply is cut off. Unlike this, the main memory device 1220 may not include the semiconductor devices according to the implementations, but may include a static random access memory (SRAM), a dynamic random access memory (DRAM), and so on, of a volatile memory type in which all contents are erased when power supply is cut off.

The auxiliary memory device 1230 is a memory device for storing program codes or data. While the speed of the auxiliary memory device 1230 is slower than the main memory device 1220, the auxiliary memory device 1230 can store a larger amount of data. The auxiliary memory device 1230 may include one or more of the above-described semiconductor devices in accordance with the implementations. For example, the auxiliary memory device 1230 may include a resistance variable element which includes a free magnetic layer, a tunnel barrier layer and a pinned magnetic layer, and a magnetic correction layer which is disposed over the resistance variable element to be separated from the resistance variable element and has a magnetization direction opposite to a magnetization direction of the pinned magnetic layer. Through this, a fabrication process of the auxiliary memory device 1230 may become easy and the reliability of the auxiliary memory device 1230 may be improved. As a consequence, a fabrication process of the system 1200 may become easy and the reliability of the system 1200 may be improved.

Also, the auxiliary memory device 1230 may further include a data storage system (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on. Unlike this, the auxiliary memory device 1230 may not include the semiconductor devices according to the implementations, but may include data storage systems (see the reference numeral 1300 of FIG. 10) such as a magnetic tape using magnetism, a magnetic disk, a laser disk using optics, a magneto-optical disc using both magnetism and optics, a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The interface device 1240 may be to perform exchange of commands and data between the system 1200 of the present implementation and an external device. The interface device 1240 may be a keypad, a keyboard, a mouse, a speaker, a mike, a display, various human interface devices (HIDs), a communication device, and so on. The communication device may include a module capable of being connected with a wired network, a module capable of being connected with a wireless network and both of them. The wired network module may include a local area network (LAN), a universal serial bus (USB), an Ethernet, power line communication (PLC), such as various devices which send and receive data through transmit lines, and so on. The wireless network module may include Infrared Data Association (IrDA), code division multiple access (CDMA), time division multiple access (TDMA), frequency division multiple access (FDMA), a wireless LAN, Zigbee, a ubiquitous sensor network (USN), Bluetooth, radio frequency identification (RFID), long term evolution (LTE), near field communication (NFC), a wireless broadband Internet (Wibro), high speed downlink packet access (HSDPA), wideband CDMA (WCDMA), ultra wideband (UWB), such as various devices which send and receive data without transmit lines, and so on.

FIG. 7 is an example of configuration diagram of a data storage system implementing memory circuitry based on the disclosed technology.

Referring to FIG. 7, a data storage system 1300 may include a storage device 1310 which has a nonvolatile characteristic as a component for storing data, a controller 1320 which controls the storage device 1310, an interface 1330 for connection with an external device, and a temporary storage device 1340 for storing data temporarily. The data storage system 1300 may be a disk type such as a hard disk drive (HDD), a compact disc read only memory (CDROM), a digital versatile disc (DVD), a solid state disk (SSD), and so on, and a card type such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The storage device 1310 may include a nonvolatile memory which stores data semi-permanently. The nonvolatile memory may include a ROM (read only memory), a NOR flash memory, a NAND flash memory, a phase change random access memory (PRAM), a resistive random access memory (RRAM), a magnetic random access memory (MRAM), and so on.

The controller 1320 may control exchange of data between the storage device 1310 and the interface 1330. To this end, the controller 1320 may include a processor 1321 for performing an operation for, processing commands inputted through the interface 1330 from an outside of the data storage system 1300 and so on.

The interface 1330 is to perform exchange of commands and data between the data storage system 1300 and the external device. In the case where the data storage system 1300 is a card type, the interface 1330 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. In the case where the data storage system 1300 is a disk type, the interface 1330 may be compatible with interfaces, such as IDE (Integrated Device Electronics), SATA (Serial Advanced Technology Attachment), SCSI (Small Computer System Interface), eSATA (External SATA), PCMCIA (Personal Computer Memory Card International Association), a USB (universal serial bus), and so on, or be compatible with the interfaces which are similar to the above mentioned interfaces. The interface 1330 may be compatible with one or more interfaces having a different type from each other.

The temporary storage device 1340 can store data temporarily for efficiently transferring data between the interface 1330 and the storage device 1310 according to diversifications and high performance of an interface with an external device, a controller and a system. The temporary storage device 1340 for temporarily storing data may include one or more of the above-described semiconductor devices in accordance with the implementations. The temporary storage device 1340 may include a variable resistance element having a first electrode, a variable resistance layer, and a second electrode which are sequentially stacked therein; a spacer formed on the sidewall of the variable resistance element; and a conductive line covering the variable resistance element including the spacer. The second electrode is electrically connected to the conductive line, and the variable resistance layer and the first electrode are electrically isolated from the conductive line by the spacer. By using the conductive line which covers the variable resistance element including the spacer, a contact resistance between the conductive line and the variable resistance element is decreased and a contact defect between the conductive line and the variable resistance element is prevented. Through this, operating characteristic of temporary storage device 1340 and the storage system 1300 having temporary storage device 1340 is improved. As a consequence, it is possible to realize a high performance of the storage system 1300.

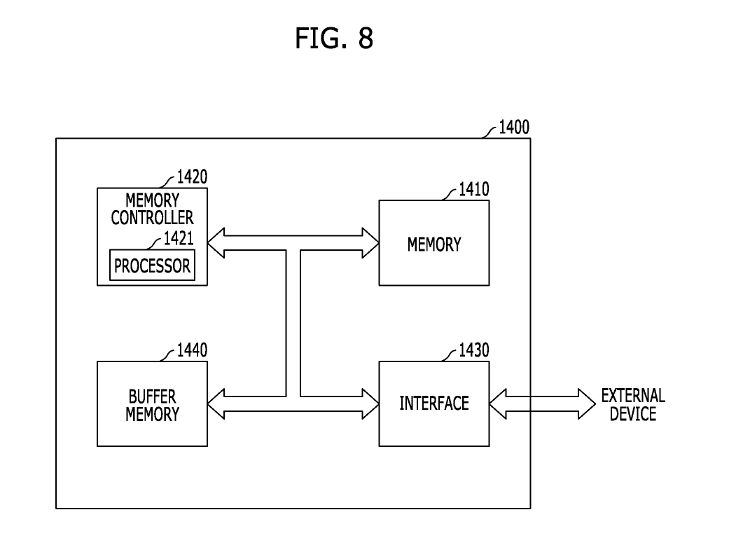

FIG. 8 is an example of configuration diagram of a memory system implementing memory circuitry based on the disclosed technology.

Referring to FIG. 8, a memory system 1400 may include a memory 1410 which has a nonvolatile characteristic as a component for storing data, a memory controller 1420 which controls the memory 1410, an interface 1430 for connection with an external device, and so on. The memory system 1400 may be a card type such as a solid state disk (SSD), a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on.

The memory 1410 for storing data may include one or more of the above-described semiconductor devices in accordance with the implementations. For example, the memory 1410 may include a variable resistance element having a first electrode, a variable resistance layer, and a second electrode which are sequentially stacked therein; a spacer formed on the sidewall of the variable resistance element; and a conductive line covering the variable resistance element including the spacer. The second electrode is electrically connected to the conductive line, and the variable resistance layer and the first electrode are electrically isolated from the conductive line by the spacer. By using the conductive line which covers the variable resistance element including the spacer, a contact resistance between the conductive line and the variable resistance element can be decreased and a contact defect between the conductive line and the variable resistance element is prevented. Through this, operating characteristic of the memory 1410 and the memory system 1400 having the memory 1410 is improved. As a consequence, it is possible to realize a high performance of the memory system 1400.

Also, the memory 1410 according to the present implementation may further include a ROM (read only memory), a NOR flash memory, a NAND flash memory, a phase change random access memory (PRAM), a resistive random access memory (RRAM), a magnetic random access memory (MRAM), and so on, which have a nonvolatile characteristic.

The memory controller 1420 may control exchange of data between the memory 1410 and the interface 1430. To this end, the memory controller 1420 may include a processor 1421 for performing an operation for and processing commands inputted through the interface 1430 from an outside of the memory system 1400.

The interface 1430 is to perform exchange of commands and data between the memory system 1400 and the external device. The interface 1430 may be compatible with interfaces which are used in devices, such as a USB memory (universal serial bus memory), a secure digital (SD) card, a mini secure digital (mSD) card, a micro secure digital (micro SD) card, a secure digital high capacity (SDHC) card, a memory stick card, a smart media (SM) card, a multimedia card (MMC), an embedded MMC (eMMC), a compact flash (CF) card, and so on, or be compatible with interfaces which are used in devices similar to the above mentioned devices. The interface 1430 may be compatible with one or more interfaces having a different type from each other.

The memory system 1400 according to the present implementation may further include a buffer memory 1440 for efficiently transferring data between the interface 1430 and the memory 1410 according to diversification and high performance of an interface with an external device, a memory controller and a memory system. For example, the buffer memory 1440 for temporarily storing data may include one or more of the above-described semiconductor devices in accordance with the implementations. The buffer memory 1440 may include a resistance variable element. Through this, a fabrication process of the buffer memory 1440 may become easy and the reliability of the buffer memory 1440 may be improved. As a consequence, a fabrication process of the memory system 1400 may become easy and the reliability of the memory system 1400 may be improved.

Moreover, the buffer memory 1440 according to the present implementation may further include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic. Unlike this, the buffer memory 1440 may not include the semiconductor devices according to the implementations, but may include an SRAM (static random access memory), a DRAM (dynamic random access memory), and so on, which have a volatile characteristic, and a phase change random access memory (PRAM), a resistive random access memory (RRAM), a spin transfer torque random access memory (STTRAM), a magnetic random access memory (MRAM), and so on, which have a nonvolatile characteristic.

As is apparent from the above descriptions, in the semiconductor device and the method for fabricating the same in accordance with the implementations, patterning of a resistance variable element is easy, and it is possible to secure the characteristics of the resistance variable element.

Features in the above examples of electronic devices or systems in FIGS. 8-12 based on the memory devices disclosed in this document may be implemented in various devices, systems or applications. Some examples include mobile phones or other portable communication devices, tablet computers, notebook or laptop computers, game machines, smart TV sets, TV set top boxes, multimedia servers, digital cameras with or without wireless communication functions, wrist watches or other wearable devices with wireless communication capabilities.

While this patent document contains many specifics, these should not be construed as limitations on the scope of any invention or of what may be claimed, but rather as descriptions of features that may be specific to particular embodiments of particular inventions. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. Moreover, the separation of various system components in the embodiments described in this patent document should not be understood as requiring such separation in all embodiments.

Only a few implementations and examples are described. Other implementations, enhancements and variations can be made based on what is described and illustrated in this patent document.

What is claimed is:

1. An electronic device comprising a semiconductor memory unit that includes:
a variable resistance element including a stacked structure of a first electrode, a variable resistance layer, and a second electrode;
a spacer formed on a sidewall of the variable resistance element; and
a conductive line covering the variable resistance element including the spacer.

2. The electronic device of claim 1,
wherein the second electrode is electrically connected to the conductive line, and
the variable resistance layer and the first electrode are electrically isolated from the conductive line by the spacer.

3. The electronic device of claim 1, wherein the conductive line is shaped to completely cover the variable resistance element including the spacer.

4. The electronic device of claim 1, wherein the variable resistance element comprises a stacked layer of two magnetic layers with a tunnel barrier layer interposed therebetween.

5. The electronic device of claim 1, wherein the variable resistance layer comprises a metal oxide.

6. The electronic device of claim 1, wherein the variable resistance layer comprises a phase change material.

7. The electronic device according to claim 1, further comprising a microprocessor which includes:
a control unit configured to receive a signal including a command from an outside of the microprocessor, and performs extracting, decoding of the command, or controlling input or output of a signal of the microprocessor;
an operation unit configured to perform an operation based on a result that the control unit decodes the command; and
a memory unit configured to store data for performing the operation, data corresponding to a result of performing the operation, or an address of data for which the operation is performed,
wherein the semiconductor memory unit is part of the memory unit in the microprocessor.

8. The electronic device according to claim 1, further comprising a processor which includes:
a core unit configured to perform, based on a command inputted from an outside of the processor, an operation corresponding to the command, by using data;
a cache memory unit configured to store data for performing the operation, data corresponding to a result of performing the operation, or an address of data for which the operation is performed; and
a bus interface connected between the core unit and the cache memory unit, and configured to transmit data between the core unit and the cache memory unit,
wherein the semiconductor memory unit is part of the cache memory unit in the processor.

9. The electronic device according to claim 1, further comprising a processing system which includes:
a processor configured to decode a command received by the processor and control an operation for information based on a result of decoding the command;
an auxiliary memory device configured to store a program for decoding the command and the information;
a main memory device configured to call and store the program and the information from the auxiliary memory device such that the processor can perform the operation using the program and the information when executing the program; and
an interface device configured to perform communication between at least one of the processor, the auxiliary memory device and the main memory device and the outside,
wherein the semiconductor memory unit is part of the auxiliary memory device or the main memory device in the processing system.

10. The electronic device according to claim 1, further comprising a data storage system which includes:
a storage device configured to store data and conserve stored data regardless of power supply;
a controller configured to control input and output of data to and from the storage device according to a command inputted form an outside;
a temporary storage device configured to temporarily store data exchanged between the storage device and the outside; and
an interface configured to perform communication between at least one of the storage device, the controller and the temporary storage device and the outside,
wherein the semiconductor memory unit is part of the storage device or the temporary storage device in the data storage system.

11. The electronic device according to claim 1, further comprising a memory system which includes:
a memory configured to store data and conserve stored data regardless of power supply;
a memory controller configured to control input and output of data to and from the memory according to a command inputted form an outside;
a buffer memory configured to buffer data exchanged between the memory and the outside; and
an interface configured to perform communication between at least one of the memory, the memory controller and the buffer memory and the outside,
wherein the semiconductor memory unit is part of the memory or the buffer memory in the memory system.

12. An electronic device comprising a semiconductor memory unit that includes:
an interlayer dielectric layer formed over a substrate including a switching element;
a contact plug connected to the switching element through the interlayer dielectric layer;
a variable resistance element formed over the interlayer dielectric layer so as to be connected to the contact plug, and including a first electrode, a variable resistance layer, and a second electrode which are stacked;
a spacer formed on each sidewall of the variable resistance element; and
a conductive line formed over the interlayer dielectric layer so as to cover the variable resistance element including the spacer.

13. The electronic device of claim 12, wherein the second electrode is electrically connected to the conductive line, and
the variable resistance layer and the first electrode are electrically isolated from the conductive line by the spacer.

14. The electronic device of claim 12, wherein the conductive line is shaped to completely cover the variable resistance element including the spacer.

15. The electronic device of claim 12, wherein the variable resistance element has a line shape extended in the same direction as the conductive line.

16. The electronic device of claim 12, wherein the semiconductor memory unit includes a plurality of variable resistance elements each having a pillar shape,
wherein the plurality of variable resistance elements are arranged to be spaced at a predetermined distance from one another in the direction where the conductive line is extended and in contact with the variable resistance elements.

17. The electronic device of claim 12, wherein the variable resistance layer comprises a stacked layer of two magnetic layers with a tunnel barrier layer interposed therebetween.

18. The electronic device of claim 12, wherein the variable resistance layer comprises a metal oxide.

19. The electronic device of claim 12, wherein the variable resistance layer comprises a phase change material.
